(19) United States
(12) Patent Application Publication
(10) Pub. No.: US 2016/0364054 A1
(43) Pub. Date: Dec. 15, 2016

(54) Encapsulating Structure of Display Panel and Method for the Display Panel

(71) Applicant: EverDisplay Optronics (Shanghai) Limited, Shanghai (CN)

(72) Inventors: Yujen Chen, Shanghai (CN); Mingyue Zhang, Shanghai (CN)

(73) Assignee: EverDisplay Optronics (Shanghai) Limited

(21) Appl. No.: 15/132,979

(22) Filed: Apr. 19, 2016

(30) Foreign Application Priority Data
Jun. 10, 2015 (CN) 201510315231.6

(51) Int. Cl. G06F 3/041; H01L 27/32; H01L 51/56; H05K 3/28; H01L 51/52

(52) U.S. Cl. CPC G06F 3/0412; H05K 3/28; H01L 51/5246; H01L 51/5275; H01L 51/56; H01L 27/323; H01L 27/3244; G06F 2203/04112; G06F 2203/04103; H01L 2227/323

(57) ABSTRACT

A encapsulating structure of a display panel includes a substrate, a frit layer disposed around a periphery of the substrate, and a touch cover lens mounted on the substrate. A metal mesh is mounted in the touch cover lens for receiving a touch control signal. A plurality of touch wires is disposed between the frit layer and the substrate and is electrically connected to the metal mesh. A method for encapsulating a display panel includes producing a plurality of touch wires on a substrate and electrically connecting the touch wires to a flexible circuit board on a side of the substrate. A glass frit is applied on the touch wires and covers the touch wires. A touch cover lens is disposed on the substrate and includes a metal mesh. The touch cover lens is bonded to the substrate by the glass frit.

### CROSS REFERENCE TO RELATED APPLICATIONS

This application is based upon and claims priority to Chinese Patent Application No201510315231.6, filed on Jun. 10, 2015, the entire contents of which are incorporated herein by reference.

### BACKGROUND

The present disclosure relates to the display field, and more particularly, to an encapsulating structure of a display panel and a method for encapsulating the display panel.

In comparison with conventional liquid crystal displays, active matrix organic light-emitting diode (AMOLED) panels include the features of high speed response, high contrast ratio, and wide visual angle. Furthermore, AMOLED panels also has the feature of self-illumination that does not require a backlight board, such that the AMOLED panels are thinner than conventional liquid crystal displays and can save the costs for the backlight modules. Thus, AMOLED panels have promising applications due to the advantages in many aspects.

An AMOLED in-cell display panel embeds the touch panel function into the pixel layer of the panel. FIG. 1 shows a top view of an in-cell AMOLED display panel according to the prior art. The in-cell display panel includes a substrate 11, a frit layer 12 disposed around a periphery of the substrate 11, a flexible circuit board 13 bonded to a side of the substrate 11, a metal mesh 15 mounted upright to a central portion of the substrate 11, and a plurality of touch wires 16 disposed on the substrate 11. A touch cover lens (not shown) is mounted on the substrate 11 and is bonded to the substrate 11 by the glass frit 11. The touch wires 16 are connected to the flexible circuit board 13. The touch wires 16 and the metal mesh 15 can sense the touch signals on the touch cover lens, and the sensed touch signals are sent out by the flexible circuit board 13. In disposition of the in-cell display panel, the touch wires 16 are disposed to the outside of the glass frit 12, the main purpose of which is to avoid failure of the encapsulating by the glass frit 12. However, the frame of the display panel becomes wider, which, in turn, makes the display device wider, adversely affecting the competitiveness.

### SUMMARY

An objective of the present disclosure is to overcome the disadvantage of the wide frame of the in-cell AMOLED display panel of the prior art by providing a encapsulating structure of a display panel and a method for encapsulating the display panel.

An encapsulating structure of a display panel according to an embodiment of the present disclosure includes a substrate, a frit layer disposed around a periphery of the substrate, and a touch cover lens mounted on the substrate. A metal mesh is mounted in the touch cover lens and is adapted for receiving a touch control signal. A plurality of touch wires are disposed between the frit layer and the substrate. The plurality of touch wires are electrically connected to the metal mesh.

Another objective of the present disclosure is to provide a method for encapsulating a display panel, which includes:

producing a plurality of touch wires on a substrate and electrically connecting the plurality of touch wires to a flexible circuit board on a side of the substrate;

applying a glass frit on the plurality of touch wires, with the glass frit covering the plurality of touch wires; and

disposing a touch cover lens on the substrate, with the touch cover lens including a metal mesh, and with the touch cover lens bonded to the substrate by the glass frit.

The present disclosure will be further described in connection with the accompanying drawings and specific embodiments.

### DESCRIPTION OF THE DRAWINGS

FIG. 1 is a top view of a conventional in-cell AMOLED display panel.

FIG. 2 is a top view of an encapsulating structure of a display panel according to an embodiment of the present disclosure, with a touch cover lens removed.

FIG. 3 is an enlarged view of a circled portion A of FIG. 2.

FIG. 4 is an enlarged view of another circled portion B of FIG. 3.

FIG. 5 is a cross sectional view taken along section line C-C of FIG. 3.

FIG. 6 is a cross sectional view taken along section line D-D of FIG. 3.

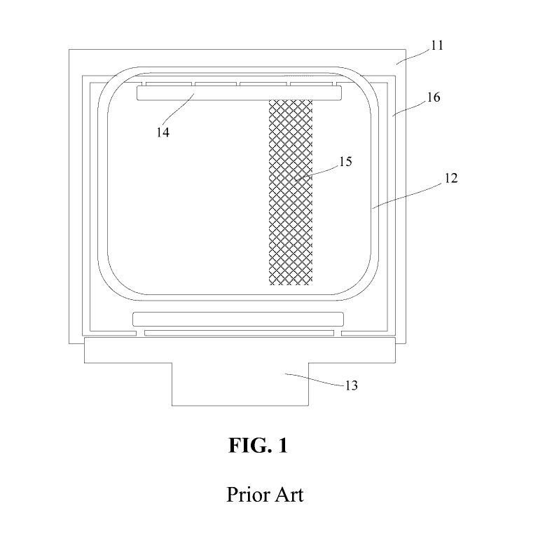

### DETAILED DESCRIPTION

The present disclosure provides an encapsulating structure of a display panel and a method for encapsulating the display panel and, more particularly, relates to an in-cell AMOLED panel structure. According to the encapsulating structure of a display panel and the method for encapsulating a display panel, the frame of the display panel becomes narrower by disposing the touch wires right below the frit layer, increasing the competitiveness of the display device. Furthermore, by providing a pad layer below each touch panel sensor trace, the adherence of each touch panel sensor trace is enhanced to increase the connection strength between the touch wires and the substrate, assuring the effectiveness of encapsulating. The encapsulating structure of a display panel and the method for encapsulating a display panel according to the present disclosure will be set forth hereinafter in connection with the accompanying drawings.

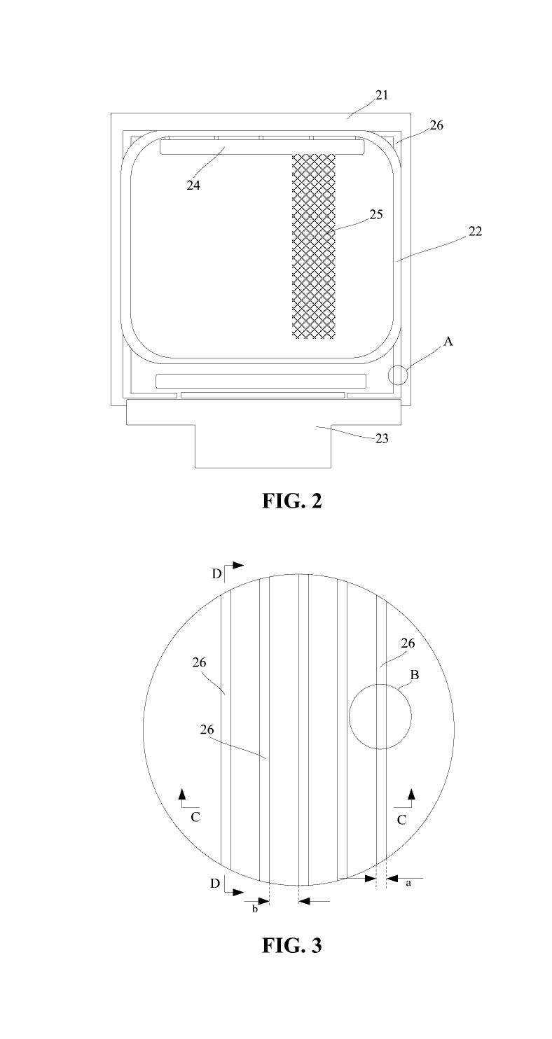

FIG. 2 is a top view of an encapsulating structure of a display panel according to the present disclosure. The encapsulating structure of the display panel according to the present disclosure will be set forth hereinafter in connection with FIG. 2.

As shown in FIG. 2, the encapsulating structure of the display panel according to the present disclosure includes a substrate 21, a frit layer 22 disposed around a periphery of the substrate 21, a flexible circuit board 23 bonded to a side of the substrate 21, and a touch cover lens mounted on the substrate 21. The touch cover lens and the substrate 21 are packaged together by the frit layer 22. The encapsulating structure of a display panel according to the present disclosure further includes a plurality of touch wires 26 also disposed around the periphery of the substrate 21. The touch wires 26 are disposed between the frit layer 22 and the substrate 21, are located right below the frit layer 22, and overlap with the frit layer 22. The touch wires 26 are covered by the frit layer 22. The touch wires 26 are electrically connected to the flexible circuit board 23.

The encapsulating structure of the display panel further includes a metal mesh 25 mounted in the touch cover lens. The metal mesh 25 is adapted for receiving a touch control signal. The metal mesh 25 is connected to the touch wires 26 via a conductive glue layer 24. The touch control signal on the touch cover lens can be sensed via the metal mesh 25 and the touch wires 26 and can be sent out by the flexible circuit board 23. The metal mesh 25 extends over the touch cover lens. FIG. 2 is merely a diagrammatic view.

FIG. 3 is an enlarged view of a circled portion A of FIG. 2. The structure of the touch wires 26 will be set forth hereinafter in connection with FIG. 3.

As shown in FIG. 3, the touch wires 26 are disposed on a bonding face of the substrate 21 and are spaced from each other. Each touch wire 26 has a width a. Each two adjacent touch wires 26 have a spacing b there between. To assure the transmission function of the touch wires 26 and to avoid mutual interference between the touch wires 26, the ratio of the width a to the spacing b is controlled to be in a range between 1:3 and 1:10. In disposition, the frit layer 22 covers the touch wires 26 to make the touch wires 26 overlap with the frit layer 22, effectively reducing the width of the frame of the display panel while assuring effective encapsulating.

With reference to FIG. 4, to increase the metal adherence of the touch wires 26, each touch wire 26 includes a pad layer disposed on the bonding face of the substrate 21 and having a plurality of pads 261 spaced from each other. Namely, the pads 261 are disposed on the back side of the touch wires 26 and are spaced from each other. The pads 261 in the pad layer are made of a material for enhancing the metal adherence without causing signal interference, such as silicon oxide or silicon nitride. A ratio of the width c of each pad 261 to the width of each touch wire 26 is controlled to be in a range between 2:5 and 4:5 to assure the transmission function of the metal wires. With regard to the density of the pads 261, disposition of the pads 261 should be uniform. An area of each pad layer is ⅕ to ⅓ of an area of each of touch wire 26. In this embodiment, each pad 261 has square cross sections. However, each pad 261 can have other shapes in cross section, such as rectangular, circular, etc.

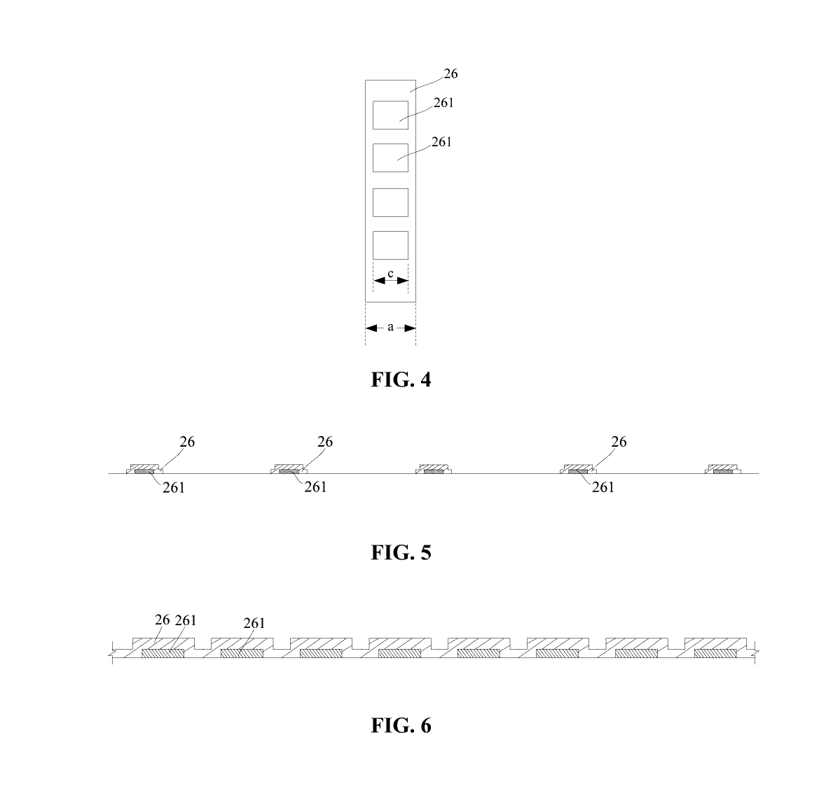

As shown in FIGS. 5 and 6, the pads 261 are spaced disposed on each touch wire 26. Preferably, each pad 261 is centered on the corresponding touch wire 26 in the horizontal direction, and the pads 261 are disposed on the corresponding touch wire 26 in the longitudinal direction. The thickness of each pad 261 is smaller than the thickness of each touch wire 26. The back side of each touch wire 26 abuts the substrate 21, and the pads 261 on the back side of each touch wire 26 also abut the substrate 21, increasing the adherence between the touch wires 26 and the substrate 21.

Preferably, the pads 261 can be disposed on the touch wires 26 by spin coating, sputtering, chemical vapor deposition (CVD), physical vapor deposition (PVD), high frequency sputtering, magnetron sputtering, thermal spray coating, thermal deposition, or coating.

Experiments on two groups (first and second groups) of the encapsulating structure of a display panel according to an embodiment of the present disclosure were conducted. The experiment conditions included: the size of the display panels was 6 inches, the display panels were in-cell touch AMOLED panels, the touch wires were disposed below the frit and overlapped with the frit after encapsulating, the pads on the back sides of the touch wires were made of SiOx, the producing procedures (screen printing, oven, and encapsulating) of the first group and the second group were the same, and the package testing method was red ink penetration test (namely, submersed in a red ink for 100 minutes). The experiment conditions of the first group and the second group were identical. No red ink was found after the red ink penetration test. Conclusively, the encapsulating structures passed the encapsulating test and were proven to be effective.

The advantageous effects of the encapsulating structure of the display panel according to the present disclosure are as follows.

The width of the frame of the display panel can be effectively reduced by disposing the touch wires right below the frit layer. In comparison with the conventional in-cell display panel structure, the width of the touch wires 26 and the spacing between the touch wires 26 and the glass frit can be reduced. Thus, the width of the display panel becomes narrower while assuring the encapsulating effect of the frit layer 22. Furthermore, by providing a pad layer below each touch wire 26, the adherence of each touch panel sensor trace is enhanced to increase the connection strength between the touch wires 26 and the substrate 21, assuring the encapsulating effect.

The method for encapsulating a display panel will be set forth hereinafter.

The method for encapsulating a display panel according to an embodiment of the present disclosure is suitable for an in-cell AMOLED panel structure. The display panel structure obtained from the encapsulating method is shown in FIG. 2.

Specifically, the method for encapsulating a display panel according to an embodiment of the present disclosure includes producing a plurality of touch wires 26 on a substrate 21. The touch wires 26 are disposed on a periphery of the substrate 21. The touch wires 26 are disposed on the substrate 21 and are spaced from each other at regular intervals. As shown in FIG. 3, to assure the transmission function of the touch wires 26 and to avoid mutual interference between the touch wires 26, the ratio of the width a of each touch wire 26 to the spacing b between two adjacent touch wires 26 is controlled to be in a range between 1:3 and 1:10. After production of the touch wires 26, the touch wires 26 are electrically connected to a flexible circuit board 23 on a side of the substrate 21. The touch wires 26 can send out the applied touch signal by the flexible circuit board 23.

After disposition of the touch wires 26, a frit is coated on the touch wires 26 to form a frit layer 22. The frit layer 22 covers the touch wires 26. Then, a touch cover lens is disposed on the substrate 21. The frit layer 22 bonds and seals the touch cover lens and the substrate 21 together.

As shown in FIG. 4, the touch wires 26 are disposed on a bonding face of the substrate 21. A plurality of pad layers is disposed on the bonding face of the substrate 21 before producing the touch wires 26 on the substrate 21. Namely, each pad layer is disposed on one of the touch wires 26 and includes a plurality of spaced pads 261 disposed on the back side of the touch wire 26. Optionally, the pads 261 are disposed on the back side of each touch wire 26 and are spaced from each other at regular intervals. Each pad 261 is centered on the corresponding touch wire 26 in the horizontal direction. Namely, each pad 216 has equal spacing to the left edge and the right edge of the corresponding touch wire 26. The effect of the pads 261 is to increase the metal adherence of the touch wires 26. The pads 261 in the pad layer use material that can increase the metal adherence without causing signal interference, such as silicon oxide or silicon nitride. A ratio of the width c of each pad 261 to the width of each touch wire 26 is controlled to be in a range between 2:5 and 4:5 to assure the transmission function of the metal wires. With regard to the density of the pads 261, disposition of the pads 261 should be uniform. An area of each pad layer is ⅕ to ⅓ of an area of each of touch wire 26. In this embodiment, each pad 261 has square cross sections. However, each pad 261 can have other shapes in cross section, such as rectangular, circular, etc.

As shown in FIGS. 5 and 6, the pads 261 are spaced disposed on each touch wire 26. The thickness of each pad 261 is smaller than the thickness of each touch wire 26. The back side of each touch wire 26 abuts the substrate 21, and the pads 261 on the back side of each touch wire 26 also abut the substrate 21, increasing the adherence between the touch wires 26 and the substrate 21.

Preferably, the pads 261 can be disposed on the touch wires 26 by spin coating, sputtering, chemical vapor deposition (CVD), physical vapor deposition (PVD), high frequency sputtering, magnetron sputtering, thermal spray coating, thermal deposition, or coating.

Experiments on two groups (first and second groups) of the encapsulating structure of a display panel according to the present disclosure were conducted. The experiment conditions included: the size of the display panels was 6 inches, the display panels were in-cell touch AMOLED panels, the touch wires were disposed below the glass frit and overlapped with the glass frit after encapsulating, the pads on the back sides of the touch wires were made of SiOx, the producing procedures (screen printing, oven, and encapsulating) of the first group and the second group were the same, and the package testing method was red ink penetration test (namely, submersed in a red ink for 100 minutes). The experiment conditions of the first group and the second group were identical. No red ink was found after the red ink penetration test. Conclusively, the encapsulating structures passed the encapsulating test and were proven to be effective.

Although the disclosure has been described in connection with the embodiments shown in the accompanying drawings, a person having ordinary skill in the art can make various modifications to the disclosure based on the above descriptions. Therefore, some details of the embodiment should not be construed to restrict the disclosure. The scope of the disclosure is limited by the accompanying claims.

1. An encapsulating structure of a display panel comprising a substrate, a frit layer disposed around a periphery of the substrate, and a touch cover lens disposed above the substrate, with a metal mesh disposed on the touch cover lens and adapted for receiving a touch signal, with a plurality of touch wires disposed between the frit layer and the substrate, and with the plurality of touch wires electrically connected to the metal mesh.

2. The encapsulating structure of a display panel as claimed in claim 1, wherein the plurality of touch wires are disposed on a bonding face of the substrate and respectively comprises a pad layer disposed on the bonding face of the substrate, and the pad layer comprises a plurality of pads spaced from each other.

3. The encapsulating structure of a display panel as claimed in claim 2, wherein the pad layer is made of silicon oxide or silicon nitride.

4. The encapsulating structure of a display panel as claimed in claim 2, wherein a ratio of a width of each of the plurality of pads to a width of each of the plurality of touch wires is in a range between 2:5 and 4:5.

5. The encapsulating structure of a display panel as claimed in claim 2, wherein an area of pad layer is ⅕ to ⅓ of an area of the plurality of touch wires.

6. A method for encapsulating a display panel, comprising:
producing a plurality of touch wires on a substrate and electrically connecting the plurality of touch wires to a flexible circuit board on a side of the substrate;
applying a frit on the plurality of touch wires, with the frit covering the plurality of touch wires; and
disposing a touch cover lens on the substrate, with the touch cover lens including a metal mesh, and with the touch cover lens bonded to the substrate by the frit.

7. The method for encapsulating a display panel as claimed in claim 6, with the plurality of touch wires disposed on a bonding face of the substrate, with the method further comprising disposing a pad layer on the bonding face of the substrate before producing the plurality of touch wires on the substrate, and with the pad layer including a plurality of pads spaced from each other.

8. The method for encapsulating a display panel as claimed in claim 7, wherein the pad layer is made of silicon oxide or silicon nitride.

9. The method for encapsulating a display panel as claimed in claim 7, wherein a ratio of a width of each of the plurality of pads to a width of each of the plurality of touch wires is in a range between 2:5 and 4:5.

10. The method for encapsulating a display panel as claimed in claim 7, wherein an area of each of the plurality of pad layers is ⅕ to ⅓ of an area of the plurality of touch wires.
